(19) United States
(12) Patent Application Publication
(10) Pub. No.: US 2021/0210577 A1
(43) Pub. Date: Jul. 8, 2021

(54) DISPLAY MODULE AND MANUFACTURING METHOD THEREOF, AND DISPLAY DEVICE

(71) Applicant: BOE Technology Group Co., Ltd., Beijing (CN)

(72) Inventor: Wei Liu, Beijing (CN)

(21) Appl. No.: 16/772,894

(22) PCT Filed: Dec. 18, 2019
(86) PCT No.: PCT/CN2019/126192

§ 371 Date: Jun. 15, 2020

(30) Foreign Application Priority Data
Feb. 20, 2019 (CN) 201910125635.7

(51) Int. Cl. H01L 27/32

(52) U.S. Cl. CPC H01L 27/3269; H01L 2227/323

(57) ABSTRACT

The present disclosure, pertaining to the field of display technologies, relates to a display module assembly and a manufacturing method therefor, and a display device. The display module assembly includes a display panel and a luminance adjustment assembly, wherein the display panel includes a base substrate and a photoelectric conversion unit arranged on the base substrate and is provided with a transparent region, and the photoelectric conversion unit is arranged in the transparent region and is connected to the luminance adjustment assembly; the photoelectric conversion unit is configured to convert an optical signal of ambient light in an environment where the display panel is applied to an electrical signal; and the luminance adjustment assembly is configured to adjust a luminance of the display panel based on the electrical signal obtained by conversion of the photoelectric conversion unit.

This application claims priority to Chinese Patent Application No. 201910125635.7, filed on Feb. 20, 2019, and entitled “DISPLAY MODULE ASSEMBLY AND MANUFACTURING METHOD THEREFOR AND DISPLAY DEVICE”, the entire content of which is incorporated herein by reference.

### TECHNICAL FIELD

The present disclosure relates to a display module assembly and a manufacturing method therefor, and a display device.

### BACKGROUND

With development of display technologies, transparent display module assemblies are gradually applied to windows of buildings, vehicle windows, shopwindows, and the like as novel display module assemblies. The transparent display module assembly includes a transparent display panel. The transparent display panel supports a transparent display state to enable a viewer to see images displayed by the display panel and scenes behind the display panel. For example, the shopwindow with the transparent display panel enables the viewer to see images displayed by the shopwindow and goods placed in a shop.

### SUMMARY

Embodiments of the present disclosure provide a display module assembly and a manufacturing method therefor and a display device. The technical solutions of embodiments of the present disclosure are as follows:

In a first aspect, a display module assembly is provided. The display module assembly includes a display panel and a luminance adjustment assembly, wherein the display panel includes a base substrate and a photoelectric conversion unit arranged on the base substrate and is provided with a transparent region, and the photoelectric conversion unit is arranged in the transparent region and is connected to the luminance adjustment assembly;

the photoelectric conversion unit is configured to convert an optical signal of ambient light in an environment where the display panel is applied to an electrical signal; and

the luminance adjustment assembly is configured to adjust a luminance of the display panel based on the electrical signal obtained by conversion of the photoelectric conversion unit.

Optionally, the display panel further includes a switch unit arranged on the base substrate, wherein the switch unit is connected to the photoelectric conversion unit.

Optionally, the display panel includes a display region and a non-display region; wherein the non-display region includes a non-transparent region and a transparent region, the display region includes a non-transparent region, and the switch unit is arranged in the non-transparent region of the non-display region or in the non-transparent region of the display region.

Optionally, the photoelectric conversion unit is a photodiode.

Optionally, the photoelectric conversion unit includes a first electrode, a PIN structure, and a second electrode that are sequentially superposed in a direction distal from the base substrate, the first electrode being connected to the switch unit.

Optionally, the switch unit is a thin film transistor TFT, a drain of the TFT being connected to the first electrode.

Optionally, the first electrode, the PIN structure, and the second electrode are all made of a transparent material.

Optionally, the second electrode includes a lower electrode and an upper electrode that are superposed; and the display panel further includes a passivation layer arranged between the lower electrode and the upper electrode, the passivation layer being provided with a through hole, and the upper electrode being connected to the lower electrode by the through hole.

Optionally, the display panel further includes a display unit arranged on the base substrate; and the display unit includes a TFT, an anode, a pixel defining layer, a light emitting layer, and a cathode that are sequentially arranged in a direction distal from the base substrate.

In a second aspect, a method for manufacturing a display module assembly is provided. The method includes:

forming a photoelectric conversion unit on a base substrate to obtain a display panel, wherein the display panel is provided with a transparent region, and the photoelectric conversion unit is arranged in the transparent region;

forming a luminance adjustment assembly; and

connecting the luminance adjustment assembly with the photoelectric conversion unit to obtain the display module assembly,

wherein the photoelectric conversion unit is configured to convert an optical signal of ambient light in an environment where the display panel is applied to an electrical signal; and

the luminance adjustment assembly is configured to adjust a luminance of the display panel based on the electrical signal obtained by conversion of the photoelectric conversion unit.

Optionally, before forming the photoelectric conversion unit on the base substrate, the method further includes forming a switch unit on the base substrate; and

forming the switch unit on the base substrate, includes: forming a photoelectric conversion unit on the base substrate where the switch unit is formed, wherein the switch unit is connected to the photoelectric conversion unit.

Optionally, the photoelectric conversion unit is a photodiode, and forming the photoelectric conversion unit on the base substrate where the switch unit is formed includes:

sequentially forming a first electrode and a PIN structure on the base substrate where the switch unit is formed, wherein the first electrode is connected to the switch unit; and

forming a second electrode on the base substrate where the PIN structure is formed, wherein the first electrode, the PIN structure, and the second electrode are sequentially superposed in a direction distal from the base substrate.

Optionally, forming the switch unit on the base substrate includes forming a TFT on the base substrate, wherein a drain of the TFT is connected to a first electrode.

Optionally, forming the second electrode on the base substrate where the PIN structure is formed includes forming a lower electrode on the base substrate where the PIN structure is formed;

the method further includes forming a passivation layer on the base substrate where the lower electrode is formed, wherein the passivation layer is provided with a through hole, and the lower electrode is partially exposed by the through hole; and

forming the second electrode on the base substrate where the PIN structure is formed further includes forming an upper electrode on the base substrate where the passivation layer is formed, wherein the upper electrode is connected to the lower electrode by the through hole.

Optionally, the method further includes: forming a display unit on the base substrate.

In a third aspect, a display device is provided. The display device includes the display module assembly according to the first aspect or any one of embodiments of the first aspect.

### BRIEF DESCRIPTION OF THE DRAWINGS

FIG. 1 is a schematic top view of a display panel according to an embodiment of the present disclosure;

FIG. 2 is a schematic top view of a display module assembly according to an embodiment of the present disclosure;

FIG. 3 is a schematic enlarged view of a partial region of the display module assembly shown in FIG. 2;

FIG. 4 is a schematic enlarged view of another display module assembly according to an embodiment of the present disclosure;

FIG. 5 is a schematic sectional view taken along position A to position B of the display module assembly shown in FIG. 4;

FIG. 6 is a schematic view of a PIN structure according to an embodiment of the present disclosure;

FIG. 7 is a schematic sectional view taken along position C to position D of the display module assembly shown in FIG. 4;

FIG. 8 is a flowchart of a method for manufacturing the display module assembly according to an embodiment of the present disclosure;

FIG. 9 is a flowchart of another method for manufacturing the display module assembly according to an embodiment of the present disclosure;

FIG. 10 is a flowchart of a method for forming a photoelectric conversion unit according to an embodiment of the present disclosure; and

FIG. 11 is a flowchart of a method for forming a second electrode according to an embodiment of the present disclosure.

### DETAILED DESCRIPTION

For clearer descriptions of the principles and technical solutions in the present disclosure, the present disclosure is described in detail below in combination with the accompanying drawings. Apparently, the described embodiments are merely some embodiments, rather than all embodiments, of the present disclosure. Based on the embodiments of the present disclosure, all other embodiments derived by a person of ordinary skill in the art without creative efforts shall fall within the protection scope of the present disclosure.

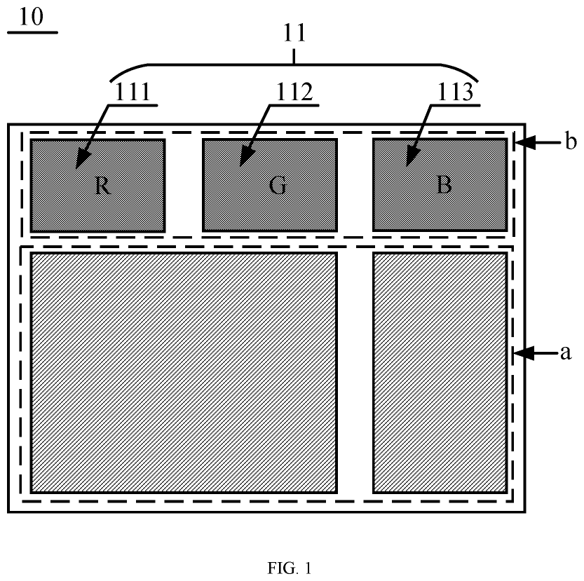

FIG. 1 is a schematic top view of the display panel 10 according to an embodiment of the present disclosure. The display panel 10 is provided with a transparent region and a non-transparent region b. The non-transparent region b is provided with a pixel unit 11 used for displaying. The pixel unit 11 includes a red subpixel unit 111, a green subpixel unit 112, and a blue subpixel unit 113.

At present, when the display panel 10 is applied to the display device, at least one of following two methods are typically adopted to perform luminance adjustment on the display panel 10:

In a first method, the display device is internally provided with a luminance adjustment button, and a user may manually adjust the luminance of the display panel by the luminance adjustment button. However, the accuracy of manual adjustment is relatively low, and the process of manual adjustment is relatively complex.

In a second method, the display device is internally provided with a photosensitive region used for sensing ambient light, the photosensitive region is arranged outsides the display panel, and the display device adjusts the luminance of the display panel according to the luminance, sensed by the photosensitive region, of the ambient light. However, as the photosensitive region is arranged outsides the display panel, the accuracy of adjusting the luminance of the display panel according to the luminance sensed by the photosensitive region is relatively low, and the condition of false adjustment is easy to occur. Furthermore, the appearance design of the display device may be further influenced as the photosensitive region is arranged outsides the display panel.

The embodiment of the present disclosure provides a display module assembly and a manufacturing method therefor and a display device. The display module assembly includes a display panel and a luminance adjustment assembly. A transparent region of the display panel is internally provided with a photoelectric conversion unit. The photoelectric conversion unit may convert an optical signal of ambient light in an environment where the display panel is applied to an electrical signal. The luminance adjustment assembly may adjust the luminance of the display panel based on the electrical signal obtained by conversion of the photoelectric conversion unit. As the luminance of the display panel does not need to be manually adjusted, and the photoelectric conversion unit is arranged in the display panel, the accuracy of luminance adjustment on the display panel is relatively high. Furthermore, the photoelectric conversion unit is made of a transparent material and is arranged in the transparent region, and the transparent region is arranged in a non-display region, such that the photoelectric conversion unit does not affect the aperture rate and the resolution of the display panel. That is, in a solution according to the embodiment of the present disclosure, adjustment on the luminance of the display panel is achieved on the condition that the aperture rate and the resolution of the display panel are not affected. For the detailed solution of the present disclosure, reference may be made to description of the following examples.

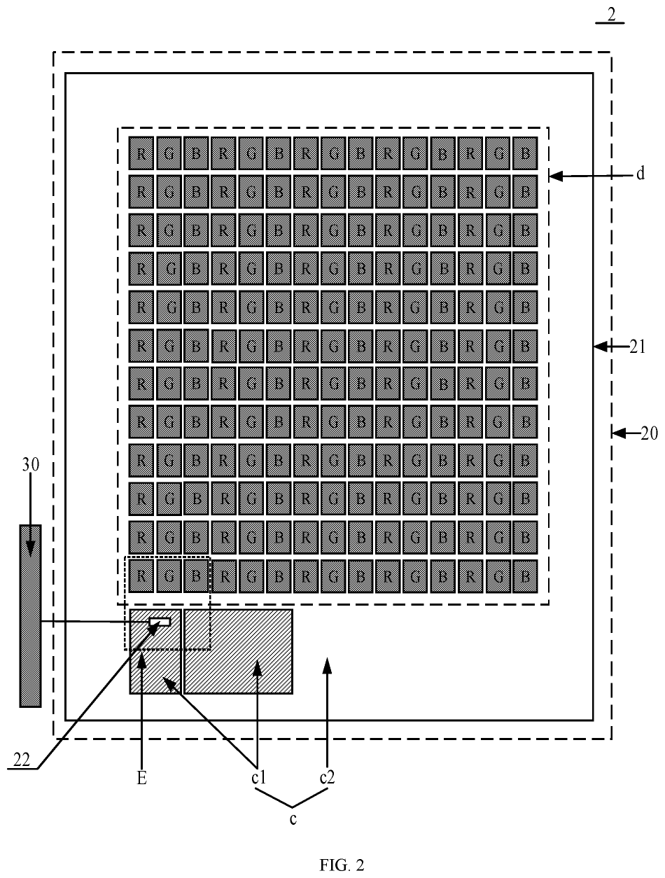

FIG. 2 is a schematic top view of a display module assembly according to an embodiment of the present disclosure, and FIG. 3 is a schematic enlarged view of a partial region of the display module assembly shown in FIG. 2. Referring to FIG. 2 and FIG. 3, the display panel 20 includes a display region d and a non-display region c, the display region d includes a non-transparent region (not shown in both FIG. 2 and FIG. 3), the non-display region c includes a transparent region c1 and a non-transparent region c2, the display region d is provided with multiple pixel units arranged in an array (not shown in both FIG. 2 and FIG. 3), and each pixel unit includes a red subpixel (not shown in both FIG. 2 and FIG. 3), a green subpixel (not shown in both FIG. 2 and FIG. 3) and a blue subpixel (not shown in both FIG. 2 and FIG. 3).

As shown in FIG. 2 and FIG. 3, the display module assembly 2 includes a display panel 20 and a luminance adjustment assembly 30. The display panel 20 includes a base substrate 21 and a photoelectric conversion unit 22 arranged on the base substrate 21 and is provided with a transparent region c1, and the photoelectric conversion unit 22 is arranged in the transparent region c1 and is connected to the luminance adjustment assembly 30.

The photoelectric conversion unit 22 is configured to convert an optical signal of ambient light in an environment where the display panel is applied to an electrical signal, and the luminance adjustment assembly 30 is configured to adjust the luminance of the display panel 20 based on the electrical signal obtained by conversion of the photoelectric conversion unit 22.

In summary, the display module assembly according to the embodiment of the present disclosure includes a display panel and a luminance adjustment assembly. The display panel includes a photoelectric conversion unit. The photoelectric conversion unit is arranged in the transparent region of the display panel, is connected to the luminance adjustment assembly, and may convert the optical signal of the ambient light in the environment where the display panel is applied to the electrical signal. The luminance adjustment assembly may adjust the luminance of the display panel based on the electrical signal obtained by conversion of the photoelectric conversion unit. As the photoelectric conversion unit is arranged in the display panel, the accuracy of adjusting the luminance of the display panel based on the electrical signal obtained by conversion of the photoelectric conversion unit is relatively high.

Optionally, the base substrate 21 may be a transparent substrate. For example, the base substrate may be a hard substrate made of an optical transmission non-metallic material, such as glasses, quartz, or transparent resin, with certain robustness; or the base substrate may be a flexible substrate made of a flexible material, such as polyimide (PI). The display module assembly 2 may include an integrated circuit (IC) bonded to the display panel 20, the integrated circuit may be drive IC, and the luminance adjustment assembly 30 may be a functional assembly in the integrated circuit.

The photoelectric conversion unit 22 is arranged in the transparent region c1, that is, in the non-display region c, and therefore, the influences on the aperture rate and the resolution of the display panel 20 by the photoelectric conversion unit 22 may be avoided. The display module assembly 2 according to the embodiment of the present disclosure may improve the accuracy of luminance adjustment of the display panel 20 under the condition that the aperture rate and the resolution of the display panel 20 are not affected.

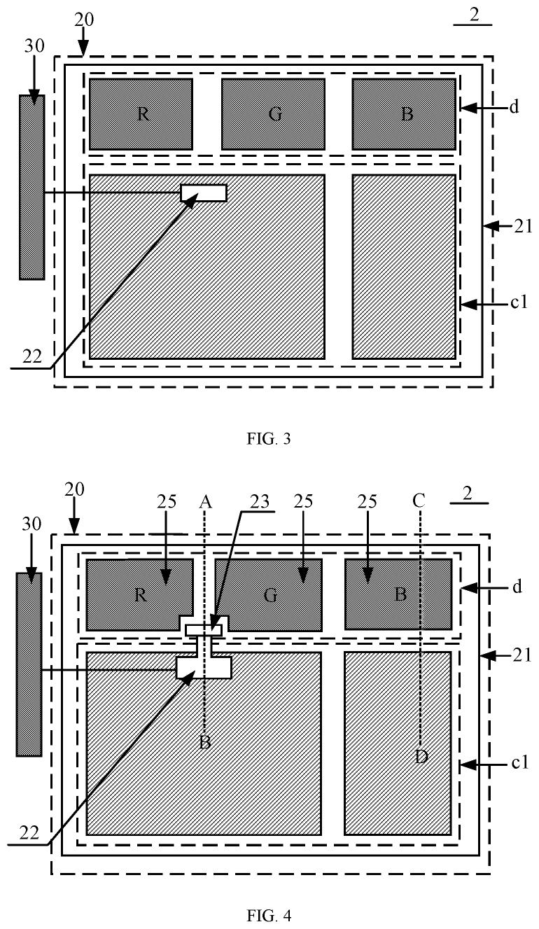

Optionally, FIG. 4 is a schematic enlarged view of another display module assembly 2 according to an embodiment of the present disclosure; on the basis of FIG. 3, the display panel 20 further includes a switch unit 23 arranged on the base substrate 21; the switch unit 23 is connected to the photoelectric conversion unit 22 and is used for on-off control on the photoelectric conversion unit 22, in other words, being used for controlling whether the photoelectric conversion unit 22 works or not; when the switch unit 23 is turned on, the photoelectric conversion unit 22 works and converts the optical signal to the electrical signal; and when the switch unit 23 is turned off, the photoelectric conversion unit 22 does not operate, that is not performing conversion between the optical signal and the electrical signal. Optionally, as shown in FIG. 4, the switch unit 23 is arranged in the display region d and specifically in the non-transparent region of the display region d. FIG. 4 gives an illustration by using the case that the switch unit 23 is arranged in the non-transparent region of the display region d as an example. In practice, the switch unit 23 may be further arranged in the non-transparent region of the non-display region. This embodiment of the present disclosure is not limited thereto. As being typically made of the non-transparent material, the switch unit 23 is arranged in the non-transparent region to be capable of avoiding influence on the transparency of the transparent region c1 by the switch unit 23.

It is to be noted that, positions of the photoelectric conversion unit 22 and the switch unit 23, shown in FIG. 4, in the display panel 20 are schematically illustrated only. In practice, the photoelectric conversion unit 22 may be further arranged at other positions in the transparent region c1, the switch unit 23 may be arranged at other positions in the non-transparent region, and this embodiment of the present disclosure is not limited thereto as long as connection between the switch unit 23 and the photoelectric conversion unit 22 may be ensured.

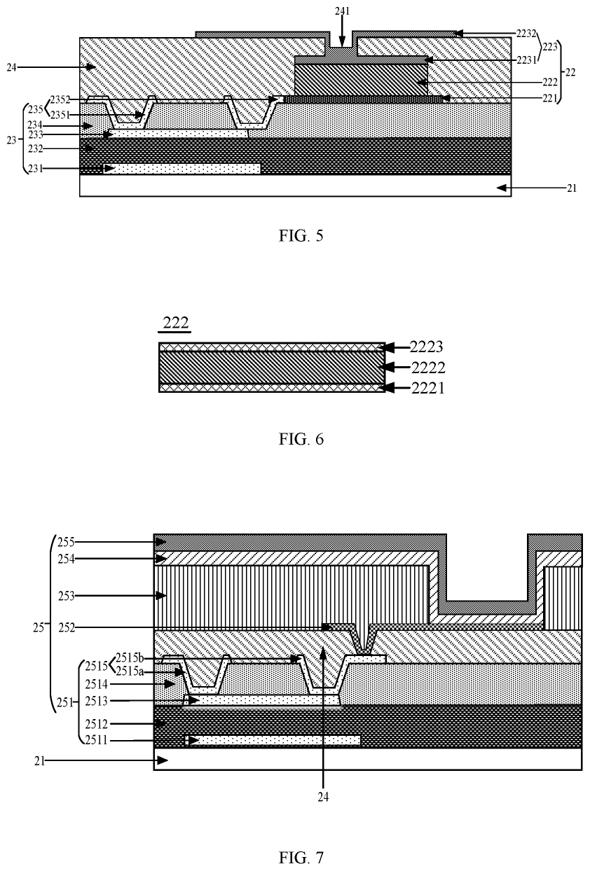

FIG. 5 is a schematic sectional view taken along position A to position B of the display module assembly 2 shown in FIG. 4. As shown in FIG. 5, the photoelectric conversion unit 22 is a photodiode and includes a first electrode 221, a PIN structure 222, and a second electrode 223 that are sequentially superposed in a direction distal from the base substrate 21. The first electrode 221 is connected to the second electrode 23. The first electrode 221, the PIN structure 222, and the second electrode 223 may be all made of a transparent material to lower the influence on the transparency of the transparent region c1 by the photoelectric conversion unit 22. For example, the first electrode 221 and the second electrode 223 may be made of an indium tin oxide (ITO), Optionally, as shown in FIG. 5, the second electrode 223 includes a lower electrode 2231 and an upper electrode 2232 that are superposed; the display panel 20 further includes a passivation layer 24 arranged between the lower electrode 2231 and the upper electrode 2232; the passivation layer 24 is provided with a through hole 241; and the upper electrode 2232 is connected to the lower electrode 2231 by the through hole 241. The upper electrode 2232 may enlarge a photosensitive region of the photoelectric conversion unit 22 for facilitating sensing of the ambient light by the photoelectric conversion unit 22. FIG. 6 is a schematic view of a PIN structure according to an embodiment of the present disclosure. The PIN structure 222 includes a P-type semiconductor layer 2221, an intrinsic semiconductor layer 2222, and an N-type semiconductor layer 2223 that are sequentially superposed. The P-type semiconductor layer 2221 may be proximal to or distal from the first electrode 221 relative to the N-type semiconductor layer 2223. This embodiment of the present disclosure is not limited thereto. The P-type semiconductor layer 2221 may be a P-type doped amorphous silicon (a-Si) film, the N-type semiconductor layer 2223 may be an N-type doped a-Si film, and the intrinsic semiconductor layer 2222 may be an a-Si film. Optionally, the P-type semiconductor layer 2221 may be doped with boron (B) ions, and the N-type semiconductor layer 2223 may be doped with phosphorus (P) ions.

The photodiode with the PIN structure 222 may also be referred to as a PIN junction photodiode. The PIN junction photodiode may perform photoelectric conversion based on the photovoltaic effect. The photoelectric conversion unit of the structure is very sensitive to illumination, and is capable of accurately sensing the ambient light and converting the optical signal of the ambient light to the electrical signal, such that the luminance adjustment assembly 30 is capable of accurately adjusting the luminance of the display panel 20. The working principle of the PIN junction photodiode is as follows: when light strikes the PIN junction photodiode, electrons of the P-type semiconductor layer 2221 and the N-type semiconductor layer 2223 are excited from covalent bonds by energy of the light, such that electron-hole pairs are produced in the PIN junction photodiode; a part of the electrons excited in the PIN junction photodiode and holes reach a space charge region before not being recombined (namely, after the PIN junction photodiode is stricken by the light, a part of the excited electrons and the holes are not captured by a “recombination center” to disappear in the process that the PIN junction photodiode tends to be stable); under the effect of an internal electric field of the space charge region, the electrons move to the positively charged N-type semiconductor layer 2223, and the holes move to the negatively charged P-type semiconductor layer 2221; and after a period of time, as the N-type semiconductor layer 2223 stores excess electrons and is negatively charged, and the P-type semiconductor layer stores excess holes and is positively charged, electromotive force is produced on the intrinsic semiconductor layer 2222 between the N-type semiconductor layer 2223 and the P-type semiconductor layer 2221, a current is correspondingly produced, and the PIN junction photodiode has a photoelectric conversion function with gradual accumulation of the current.

It is to be noted that, the structure of the photoelectric conversion unit 22 described by the embodiment of the present disclosure is illustrative only and may also be other structures as long as accurate sensing of the ambient light in the environment where the display panel is applied may be achieved in practice.

Optionally, the switch unit 23 may be a thin film transistor (TFT) and then includes a gate 231, a gate insulating layer 232, an active layer 233, an etch stop layer 234, and a source-drain layer 235 that are sequentially arranged in a direction distal from the base substrate 21, as shown in FIG. 5. The source-drain layer 235 includes a source 2351 and a drain 2352. The source 2351 is not in contact with the drain 2352. The drain 2352 is connected to the first electrode 221. It is to be noted that, as shown in FIG. 5, the embodiment of the present disclosure is described by using the case where the switch unit 23 is the TFT of a bottom gate structure as an example. In practice, the switch unit may be the TFT of a top gate structure as long as on-off control on the photoelectric conversion unit is achieved. This embodiment of the present disclosure is not limited thereto. In practice, the display module assembly 2 may further include a control assembly (not shown in the drawing), and the control assembly may be connected to the source 2351 of the switch unit, is used for controlling whether the switch unit 23 is turned on or not and may be a functional assembly in the integrated circuit of the display module assembly 2. Furthermore, referring to FIG. 5 in conjunction with FIG. 4, the gate insulating layer 232 and the etch stop layer 234 of the switch unit 23 extend to the transparent region c1 of the display panel 20, and the photoelectric conversion unit 22 may be arranged on the surface, distal from the base substrate 21, of the etch stop layer 234.

Optionally, as shown in FIG. 4, the display panel 20 further includes a display unit 25 on the base substrate 21. Then, FIG. 7 is a schematic sectional view taken along position C to position D of the display module assembly 2 shown in FIG. 4. The display unit 25 includes a TFT 251, an anode 252, a pixel defining layer 253, a light emitting layer 254, and a cathode 255 that are sequentially arranged in a direction distal from the base substrate 21. The TFT 251 includes a gate 2511, a gate insulating layer 2512, an active layer 2513, an etch stop layer 2514, and a source-drain layer 2515 that are sequentially arranged in a direction distal from the base substrate 21. The source-drain layer 2515 includes a source 2515a and a drain 2515b. The source 2515a is not in contact with the drain 2515b. The drain 2515b is connected to the anode 252. The gate insulating layer 2512 of the TFT 251 and the gate insulating layer 232 of the switch unit 23 are one film layer. The etch stop layer 2514 of the TFT 251 and the etch stop layer 234 of the switch unit 23 are one film layer. The TFT 251 may be synchronously manufactured with the switch unit 23, such that the manufacturing process of the display panel 20 is simplified, and the production efficiency is improved. It is to be noted that, in practice, the display unit 25 may cover the switch unit 23 to avoid the influence on the aperture rate of the display unit 25 and the resolution of the display panel 20 with arrangement of the switch unit 23; and in the embodiment of the present disclosure, in order to more clearly describe the entire structure of the switch unit 23 and the position of the switch unit 23 on the base substrate 21, the part, covering the switch unit 23, in the display unit 25 is not shown in FIG. 4, such that, seen from FIG. 4, the display unit 25 (that is, a red display unit R and a green display unit G in FIG. 4) has a notch.

It is to be noted that, it is not difficult to understand that the display module assembly 2 according to the embodiment of the present disclosure may automatically adjust the luminance of the display panel 20 according to the above descriptions. In practice, when the display module assembly 20 is applied to the display device, a luminance adjustment switch (or button) may be arranged in the display device, and a user may turn on or off the luminance adjustment function of the display module assembly by the luminance adjustment switch; when the luminance adjustment function of the display module assembly is turned on, the display module assembly performs luminance adjustment on the display panel based on the solution according to the embodiment of the present disclosure; and when the luminance adjustment function of the display module assembly is turned off, the display module assembly does not automatically perform luminance adjustment on the display panel.

It is further to be noted that, the display module assembly according to the embodiment of the present disclosure may be an organic light-emitting diode (OLED) display module assembly; and the structure, related to display and luminance adjustment, in the display module assembly is described only in the embodiment of the present disclosure. In practice, the display module assembly and the display panel in the display module assembly further include other structures. For example, the display panel further includes structures, such as an encapsulation structure and a cover plate, and details are not described herein.

In summary, the display module assembly according to the embodiment of the present disclosure includes a display panel and a luminance adjustment assembly. The display panel includes a photoelectric conversion unit. The photoelectric conversion unit is arranged in the transparent region of the display panel, is connected to the luminance adjustment assembly, and may convert the optical signal of the ambient light in the environment where the display panel is applied to the electrical signal. The luminance adjustment assembly may adjust the luminance of the display panel based on the electrical signal obtained by conversion of the photoelectric conversion unit. As the photoelectric conversion unit is arranged in the display panel, the accuracy of adjusting the luminance of the display panel based on the electrical signal obtained by conversion of the photoelectric conversion unit is relatively high. Furthermore, the photoelectric conversion unit is made of the transparent material and is arranged in the transparent region, and the transparent region is arranged in the non-display region, such that the photoelectric conversion unit does not affect the aperture rate and the resolution of the display panel.

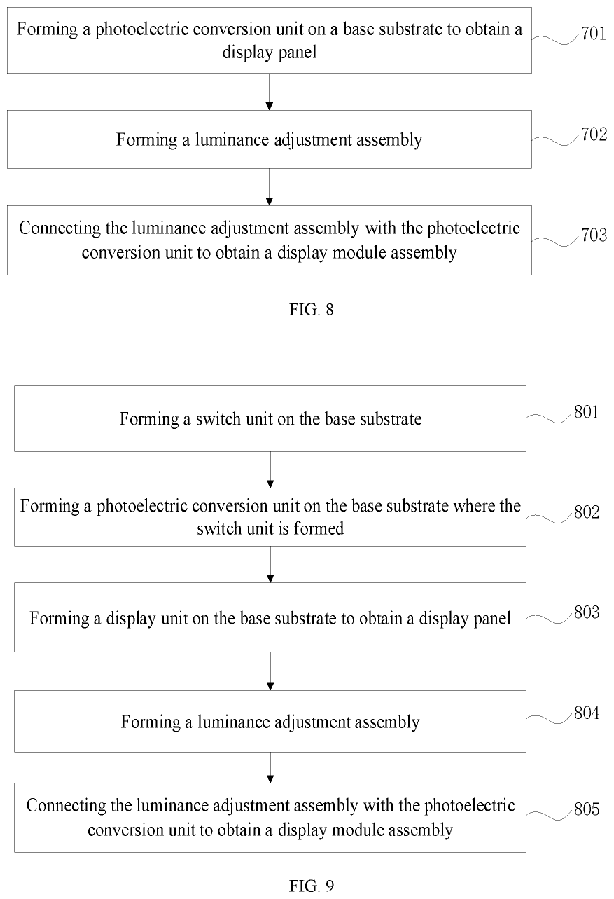

FIG. 8 is a flowchart of a method for manufacturing the display module assembly according to an embodiment of the present disclosure. The method for manufacturing the display module assembly may be used for manufacturing the display module assembly 2 according to the embodiment; and the method includes the following steps:

In step 701, a photoelectric conversion unit is formed on the base substrate to obtain a display panel.

The display panel is provided with a transparent region, and the photoelectric conversion unit is arranged in the transparent region of the display panel.

In step 702, a luminance adjustment assembly is formed.

In step 703, the luminance adjustment assembly is connected to the photoelectric conversion unit to obtain the display module.

The photoelectric conversion unit is configured to convert an optical signal of ambient light in an environment where the display panel is applied to an electrical signal; and the luminance adjustment assembly is configured to adjust a luminance of the display panel based on the electrical signal obtained by conversion of the photoelectric conversion unit.

In summary, as for the method for manufacturing the display module assembly according to the embodiment of the present disclosure, the manufactured display module assembly includes a display panel and a luminance adjustment assembly. The display panel includes a photoelectric conversion unit. The photoelectric conversion unit is arranged in the transparent region of the display panel, is connected to the luminance adjustment assembly, and may convert the optical signal of the ambient light in the environment where the display panel is applied to the electrical signal. The luminance adjustment assembly may adjust the luminance of the display panel based on the electrical signal obtained by conversion of the photoelectric conversion unit. As the photoelectric conversion unit is arranged in the display panel, the accuracy of adjusting the luminance of the display panel based on the electrical signal obtained by conversion of the photoelectric conversion unit is relatively high. Furthermore, the photoelectric conversion unit is made of the transparent material and is arranged in the transparent region, and the transparent region is arranged in the non-display region, such that the photoelectric conversion unit does not affect the aperture rate and the resolution of the display panel.

FIG. 9 is a flowchart of a method for manufacturing another display module assembly according to an embodiment of the present disclosure. The method for manufacturing the display module assembly may be used for manufacturing the display module assembly 2 according to the embodiment; and the method includes the following steps.

In step 801, a switch unit is formed on the base substrate.

Optionally, the base substrate may be a transparent substrate, for example, the base substrate may be a hard substrate made of an optical transmission non-metallic material, such as glasses, quartz, or transparent resin, with certain robustness; or the base substrate is a flexible substrate made of a flexible material, such as PI.

The switch unit may be the TFT, and forming the switch unit on the base substrate refers to forming the TFT on the base substrate. As shown in FIG. 5, forming the switch unit 23 on the base substrate 21 includes: sequentially forming a gate 231, a gate insulating layer 232, an active layer 233, an etch stop layer 234, and a source-drain layer 235 on the base substrate 21, wherein the source-drain layer 235 includes a source 2351 and a drain 2352, the source 2351 is not in contact with the drain 2352, and a through hole corresponding to the source 2351 and a through hole corresponding to the drain 2352 are formed in the etch stop layer 234, and the source 2351 and the drain 2352 are in contact with the active layer 233 via the corresponding through holes.

Illustratively, forming the switch unit 23 on the base substrate 21 may include the following steps:

In step (1), a gate material layer is formed on the base substrate 21 by chemical vapor deposition (CVD), coating, sputtering, or the like, and the gate material layer is treated by a one-time patterning process to obtain a gate 231.

In step (2), a gate insulating layer 232 is formed, by CVD, coating, sputtering, or the like, on the base substrate 21 where the gate 231 is formed.

In step (3), an active material layer is formed, by CVD, coating, sputtering, or the like, on the base substrate 21 where the gate insulating layer 232 is formed, and the active material layer is treated by the one-time patterning process to obtain an active layer 233.

In step (4), an etching material layer is formed, by CVD, coating, sputtering, or the like, on the base substrate 21 where the active material layer 233 is formed, and the etching material layer is treated by the one-time patterning process to obtain an etch stop layer 234.

In step (5), a conductive material layer is formed, by CVD, coating, sputtering, or the like, on the base substrate 21 where the etch stop layer 234 is formed, and the conductive material layer 235 is treated by the one-time patterning process to obtain a source-drain layer 235, wherein the source-drain layer 235 includes a source 2351 and a drain 2352, and the conductive material layer may be a metal material layer.

It is to noted that, as shown in FIG. 2, the display panel 20 includes non-transparent regions (including a non-transparent region of the display region d and a non-transparent region c2 of the non-display region c), the base substrate 21 is provided with regions (that is, orthographic projection regions of the non-transparent regions on the base substrate 21), corresponding to the non-transparent regions, and the switch unit 23 may be arranged in a region, corresponding to the non-transparent regions of the display panel 20, on the base substrate 21.

In step 802, a photoelectric conversion unit is formed on the base substrate where the switch unit is formed.

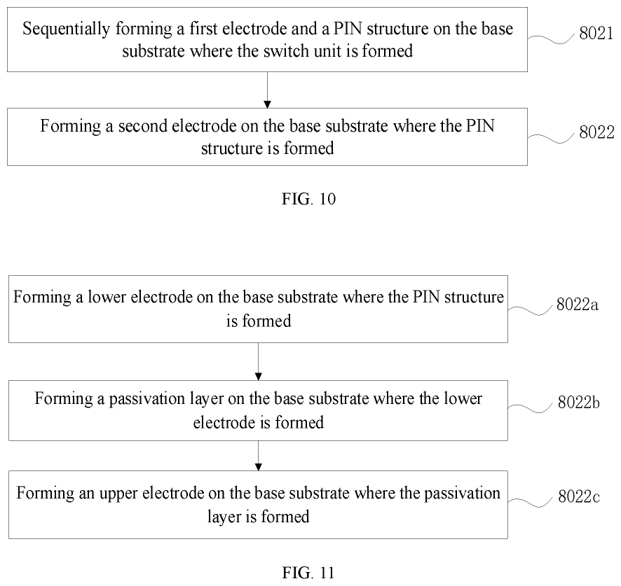

The photoelectric conversion unit may be a PIN junction photodiode. Illustratively, FIG. 10 is a flowchart of a method for forming a photoelectric conversion unit according to an embodiment of the present disclosure. The method is described by using the case where the photoelectric conversion unit is the PIN junction photodiode as an example, and may include the following sub steps.

In substep 8021, a first electrode and a PIN structure are sequentially formed on the base substrate where the switch unit is formed.

As shown in FIG. 5, the first electrode 221 is connected to the drain 2352 of the switch unit 23. Furthermore, as shown in FIG. 6, the PIN structure 222 includes a P-type semiconductor layer 2221, an intrinsic semiconductor layer 2222, and an N-type semiconductor layer 2223; and illustratively, sequentially forming the first electrode 221 and the PIN structure 222 on the base substrate 21 where the switch unit 23 is formed may include the following steps:

In step (1), a conductive material layer is formed on the base substrate 21 where the switch unit 23 is formed by CVD, coating, sputtering, or the like, and the conductive material layer is treated by the one-time patterning process to obtain the first electrode 221, wherein the conductive material layer may be an ITO material layer.

In step (2), a P-type semiconductor material layer, an intrinsic semiconductor material layer, and an N-type semiconductor material layer are sequentially formed on the base substrate 21 where the first electrode 221, and then treating the P-type semiconductor material layer, the intrinsic semiconductor material layer, and the N-type semiconductor material layer are sequentially formed by the one-time patterning process to obtain a P-type semiconductor layer 2221, an intrinsic semiconductor layer 2222, and an N-type semiconductor layer 2223, that is, a PIN structure 222, wherein forming the P-type semiconductor material layer may include forming the intrinsic semiconductor material layer by CVD, coating, sputtering, or the like, and then performing P-type doping on the intrinsic semiconductor material layer to obtain the P-type semiconductor material layer; and forming the N-type semiconductor material layer may include forming the intrinsic semiconductor material layer by CVD, coating, sputtering, or the like, and then performing N-type doping on the intrinsic semiconductor material layer to obtain the N-type semiconductor material layer. Illustratively, the P-type semiconductor material layer may be made of P-type a-Si, the intrinsic semiconductor material layer may be made of intrinsic a-Si, and the N-type semiconductor material layer may be made of N-type a-Si.

It is to be noted that the embodiment of the present disclosure is described by using forming the P-type semiconductor layer 2221, the intrinsic semiconductor layer 2222, and the N-type semiconductor layer 2223 at the same time as an example. In practice, after being formed each time, one semiconductor material layer (for example, P-type semiconductor material layer) is treated by the one-time patterning process to obtain a corresponding semiconductor layer (for example, the P-type semiconductor layer 2221).

In substep 8022, a second electrode is formed on the base substrate where the PIN structure is formed.

As shown in FIG. 5, the second electrode 223 includes a lower electrode 2231 and an upper electrode 2232 that are arranged in a superposing fashion; the display panel 20 further includes a passivation layer 24 arranged between the lower electrode 2231 and the upper electrode 2232; the passivation layer 24 is provided with a through hole 241; and the upper electrode 2232 is connected to the lower electrode 2231 by the through hole 241. Illustratively, FIG. 11 is a flowchart of a method for forming a second electrode according to an embodiment of the present disclosure. The method may include the following substeps.

In substep 8022a, a lower electrode is formed on the base substrate where the PIN structure is formed.

Illustratively, a conductive material layer may be formed, by CVD, coating, sputtering, or the like, on the base substrate 21 where the PIN unit 222 is formed and may be is treated by the one-time patterning process to obtain the lower electrode 2231. The conductive material layer may be an ITO material layer.

In substep 8022b, a passivation layer is formed on the base substrate where the lower electrode is formed.

Illustratively, a passivation layer material layer may be formed, by CVD, coating, sputtering, or the like on the base substrate 21 where the lower electrode 2231 is formed and may be treated by the one-time patterning process to obtain the passivation layer 24, wherein the passivation layer 24 is provided with a through hole 241.

In substep 8022c, an upper electrode is formed on the base substrate where the passivation layer is formed.

Illustratively, a conductive material layer may be formed, by CVD, coating, sputtering, or the like, on the base substrate 21 where the passivation layer 24 is formed, and may be treated by the one-time patterning process to obtain the upper electrode 2232, wherein the upper electrode 2232 is connected to the lower electrode 2231 by the through hole 241 formed in the passivation layer 241. The conductive material layer may be the ITO material layer.

It is to be noted that, as shown in FIG. 2, the display panel 20 includes the transparent region c1, the base substrate 21 is provided with a region (that is, an orthographic projection region of the transparent region c1 on the base substrate 21), corresponding to the transparent region c1, and an orthographic projection of the photoelectric conversion unit 21 on the base substrate 21 may be arranged in a region, corresponding to the transparent region of the display panel, on the base substrate 21.

In step 803, a display unit is formed on the base substrate to obtain a display panel.

As shown in FIG. 7, forming the display unit 25 on the base substrate 21 includes: sequentially forming a TFT 251, an anode 252, a pixel defining layer 253, a light emitting layer 254, and a cathode 255 on the base substrate 21.

Illustratively, forming the display unit 25 on the base substrate 21 may include the following steps.

In step (1), the TFT 251 is formed on the base substrate 21; and for the implementation process of this step, reference may be made to the process of forming the switch unit 23 on the base substrate 21 in step 801, and details are not described here. It is to be noted that, in practice, the process of forming the TFT 251 in step (1) and the process of forming the switch unit 23 in step 801 may be performed at the same time, and the TFT 251 in the display unit and the switch unit 23 may be arranged on one layer.

In step (2), a conductive material layer is formed, by CVD, coating, sputtering, or the like, on the base substrate 21 where the TFT 251 is formed, and the conductive material layer is treated by the one-time patterning process to obtain the anode 252.

In step (3), a pixel defining material layer is formed, by CVD, coating, sputtering, or the like, on the base substrate 21 where the anode 252 is formed, and the pixel defining material layer is treated by the one-time patterning process to obtain a pixel defining layer 253.

In step (4), a luminescent material layer is formed, by CVD, coating, sputtering, or the like, on the base substrate 21 where the pixel defining layer 253 is formed, and the luminescent material layer is treated by the one-time patterning process to obtain the light emitting layer 254. It is to be noted that, step (4) is described by using forming a light emitting layer in one color as an example; and in practice, the display panel includes the light emitting layers with different colors, for the process of forming the light emitting layer with each color, reference may be made to step (4), and details are not described here.

In step (5), a conductive material layer is formed, by CVD, coating, sputtering, or the like, on the base substrate 21 where the light emitting layer 254 is formed, and the conductive material layer is treated by the one-time patterning process to obtain the cathode 255.

In step 804, a luminance adjustment assembly is formed.

The luminance adjustment assembly may be a functional assembly in the integrated circuit; and forming the luminance adjustment refers to forming the integrated circuit. For the specific implementation, reference may be made to the related art, and details are not described here.

In step 805, the luminance adjustment assembly is connected to the photoelectric conversion unit to obtain the display module assembly.

Optionally, the luminance adjustment assembly may be a functional assembly in the integrated circuit; and as shown in FIGS. 2 to 4, the integrated circuit may be bonded to the display panel 20 to enable the luminance adjustment assembly 30 to be connected to the photoelectric conversion unit 22. Optionally, each of the display panel 20 and the integrated circuit is provided with a bonding region, and the display panel 20 may be bonded to the integrated circuit by the bonding region of the display panel 20 and the bonding region of the integrated circuit, such that the luminance adjustment assembly 30 is connected to the photoelectric conversion unit 22.

It is to be noted that, the one-time patterning process described in the embodiment of the present disclosure typically includes: photoresist coating, exposure, developing, etching and photoresist stripping

It should also be noted that an order of the steps of the method for manufacturing the display module assembly according to the embodiments of the present disclosure may be properly adjusted, and the steps may also be increased or decreased according to a case. Method to which mortifications readily figured out by those skilled in the art within the technical scope disclosed by the present disclosure shall fall within the protection scope of the present disclosure. Therefore, details are not described herein. For example, step 804 may be performed between step 803 and step 805 or before steps 801 to 803; and for another example, step 801 and the step of forming the TFT in the display unit 25 in step 803 may be performed at the same time.

In summary, as for the method for manufacturing the display module assembly according to the embodiment of the present disclosure, the manufactured display module assembly includes a display panel and a luminance adjustment assembly. The display panel includes a photoelectric conversion unit. The photoelectric conversion unit is arranged in the transparent region of the display panel, is connected to the luminance adjustment assembly, and may convert the optical signal of the ambient light in the environment where the display panel is applied to the electrical signal. The luminance adjustment assembly may adjust the luminance of the display panel based on the electrical signal obtained by conversion of the photoelectric conversion unit. As the photoelectric conversion unit is arranged in the display panel, the accuracy of adjusting the luminance of the display panel based on the electrical signal obtained by conversion of the photoelectric conversion unit is relatively high. Furthermore, the photoelectric conversion unit is made of the transparent material and is arranged in the transparent region, and the transparent region is arranged in the non-display region, such that the photoelectric conversion unit does not affect the aperture rate and the resolution of the display panel.

The embodiment of the present disclosure provides a display device. The display device includes the display module assembly 2 according to the embodiments of the present disclosure.

Other embodiments of the present disclosure would be apparent to those skilled in the art from consideration of the specification and practice of the present disclosure. This application is intended to cover any variations, uses, or adaptations of the present disclosure following the general principles thereof and including common knowledge or commonly used technical measures that are not disclosed herein. The specification and embodiments are to be considered as exemplary only, and the true scope and spirit of the present disclosure are indicated by the following claims.

It would be appreciated that the present disclosure is not limited to the exact construction that has been described above and illustrated in the accompanying drawings, and that various modifications and variations may be made without departing from the scope of the present disclosure. It is intended that the scope of the present disclosure is only subject to the appended claims.

What is claimed is:

1. A display module assembly, comprising a display panel and a luminance adjustment assembly, wherein the display panel comprises a base substrate and a photoelectric conversion unit arranged on the base substrate and is provided with a transparent region, and the photoelectric conversion unit is arranged in the transparent region and is connected to the luminance adjustment assembly;
the photoelectric conversion unit is configured to convert an optical signal of ambient light in an environment where the display panel is applied to an electrical signal; and
the luminance adjustment assembly is configured to adjust a luminance of the display panel based on the electrical signal obtained by conversion of the photoelectric conversion unit.

2. The display module assembly according to claim 1, wherein the display panel further comprises a switch unit arranged on the base substrate, the switch unit being connected to the photoelectric conversion unit.

3. The display module assembly according to claim 2, wherein the display panel comprises a display region and a non-display region, the non-display region comprising a non-transparent region and a transparent region, and the switch unit is arranged in the non-transparent region of the non-display region.

4. The display module assembly according to claim 2, wherein the photoelectric conversion unit is a photodiode.

5. The display module assembly according to claim 4, wherein the photoelectric conversion unit comprises:
a first electrode, a PIN structure, and a second electrode that are sequentially superposed in a direction distal from the base substrate, the first electrode being connected to the switch unit.

6. The display module assembly according to claim 5, wherein the switch unit is a thin film transistor TFT, a drain of the TFT being connected to the first electrode.

7. The display module assembly according to claim 5, wherein the first electrode, the PIN structure, and the second electrode are all made of a transparent material.

8. The display module assembly according to claim 5, wherein the second electrode comprises a lower electrode and an upper electrode that are superposed; and the display panel further comprises a passivation layer arranged between the lower electrode and the upper electrode, the passivation layer being provided with a through hole, and the upper electrode being connected to the lower electrode by the through hole.

9. The display module assembly according to claim 1, wherein the display panel further comprises a display unit arranged on the base substrate; and the display unit comprises a TFT, an anode, a pixel defining layer, a light emitting layer, and a cathode that are sequentially arranged in a direction distal from the base substrate.

10. A method for manufacturing a display module assembly, comprising:
forming a photoelectric conversion unit on a base substrate to obtain a display panel, wherein the display panel is provided with a transparent region, and the photoelectric conversion unit is arranged in the transparent region;
forming a luminance adjustment assembly; and
connecting the luminance adjustment assembly with the photoelectric conversion unit to obtain the display module assembly;
wherein the photoelectric conversion unit is configured to convert an optical signal of ambient light in an environment where the display panel is applied to an electrical signal; and
the luminance adjustment assembly is configured to adjust a luminance of the display panel based on the electrical signal obtained by conversion of the photoelectric conversion unit.

11. The method according to claim 10, wherein before forming the photoelectric conversion unit on the base substrate, the method further comprises forming a switch unit on the base substrate; and
forming the switch unit on the base substrate comprises: forming a photoelectric conversion unit on the base substrate where the switch unit is formed, wherein the switch unit is connected to the photoelectric conversion unit.

12. The method according to claim 11, wherein the photoelectric conversion unit is a photodiode, and forming the photoelectric conversion unit on the base substrate where the switch unit is formed comprises:
sequentially forming a first electrode and a PIN structure on the base substrate where the switch unit is formed, wherein the first electrode is connected to the switch unit; and
forming a second electrode on the base substrate where the PIN structure is formed, wherein the first electrode, the PIN structure, and the second electrode are sequentially superposed in a direction distal from the base substrate.

13. The method according to claim 12, wherein forming the second electrode on the base substrate where the PIN structure is formed comprises forming a lower electrode on the base substrate where the PIN structure is formed;
the method further comprises forming a passivation layer on the base substrate where the lower electrode is formed, wherein the passivation layer is provided with a through hole, and the lower electrode is partially exposed by the through hole; and
forming the second electrode on the base substrate where the PIN structure is formed further comprises forming an upper electrode on the base substrate where the passivation layer is formed, wherein the upper electrode is connected to the lower electrode by the through hole.

14. A display device, comprising the display module assembly as defined in claim 1.

15. The display module assembly according to claim 2, wherein the display panel comprises a display region and a non-display region, the display region comprising a non-transparent region; and the switch unit is arranged in the non-transparent region of the display region.

16. The method according to claim 11, forming the switch unit on the base substrate includes forming a TFT on the base substrate, wherein a drain of the TFT is connected to a first electrode.

17. The method according to claim 10, the method further includes:
forming a display unit on the base substrate.

18. The method according to claim 10, wherein the photoelectric conversion unit is a photodiode.

19. The method according to claim 10, wherein the photoelectric conversion unit comprises: a first electrode, a PIN structure, and a second electrode that are sequentially superposed in a direction distal from the base substrate.

20. The method according to claim 19, wherein the first electrode, the PIN structure, and the second electrode are all made of a transparent material.
